(19) United States
(12) Patent Application Publication
(10) Pub. No.: US 2025/0167144 A1
(43) Pub. Date: May 22, 2025

(54) SEMICONDUCTOR STRUCTURE, SEMICONDUCTOR CHIP INCLUDING SEMICONDUCTOR STRUCTURE AND METHOD FOR MANUFACTURING SEMICONDUCTOR STRUCTURE

(71) Applicant: Samsung Electronics Co., Ltd., Suwon-si (KR)

(72) Inventors: Junho Lee, Suwon-si (KR); JUHYEON KIM, Suwon-si (KR); SEUNGHOON YEON, Suwon-si (KR); SeungRyong Oh, Suwon-si (KR)

(21) Appl. No.: 18/665,324

(22) Filed: May 15, 2024

(30) Foreign Application Priority Data
Nov. 16, 2023 (KR) 10-2023-0159575

(51) Int. Cl. H01L 23/00; H01L 23/48; H01L 25/065

(52) U.S. Cl. CPC H01L 24/02; H01L 23/481; H01L 25/0657; H01L 2224/02311; H01L 2224/02331; H01L 2224/0235; H01L 2224/02372; H01L 2225/06513; H01L 2225/06541; H01L 2924/35121

(57) ABSTRACT

A semiconductor structure may include a first redistribution line, a first redistribution via that is positioned on the first redistribution line and has a width in the horizontal direction that decreases from a bottom end of the first redistribution via to a top end of the first redistribution via, a second redistribution line that is positioned on the first redistribution via, a dielectric that covers the first redistribution line, the first redistribution via, and the second redistribution line, and a first seed metal layer that is positioned between the lower surface of the first redistribution via and the first redistribution line, between the side surface of the first redistribution via and the dielectric, and between the lower surface of the second redistribution line and the dielectric.

### CROSS-REFERENCE TO RELATED APPLICATION(S)

This application claims priority to and the benefit of Korean Patent Application No. 10-2023-0159575, filed on Nov. 16, 2023 in the Korean Intellectual Property Office, the disclosure of which is incorporated herein by reference in its entirety.

### BACKGROUND

### (a) Field of the Invention

The present disclosure relates to a semiconductor structure, a semiconductor chip including the semiconductor structure, and a method for manufacturing the semiconductor structure.

### (b) Description of the Related Art

With the demands for smaller and lighter electronic devices, the semiconductor industry has been seeking to make semiconductor packages to be mounted in electronic devices smaller, lighter, and thinner while making semiconductor packages have higher speed, more functions, and higher capacity. Therefore, there is an increasing need for packaging technologies capable of storing more data and transmitting data at a higher rate, and as such a packaging technology, stacked semiconductor devices which are formed by stacking semiconductor dies have been being developed.

Stacked semiconductor devices are manufactured by coupling semiconductor dies, and each semiconductor die includes a redistribution structure, as a component for coupling between semiconductor dies, on a back side of a substrate. The redistribution structure is formed by disposing redistribution lines in two or more layers and coupling the redistribution lines by redistribution vias. The redistribution lines and the redistribution vias are formed by performing a semi additive processes (SAPs) and semi etch processes (SEPs).

When an SAP is performed to form redistribution vias, the redistribution vias are formed such that the size of their lower portions is smaller than the size of their upper portions. When a plurality of redistribution lines and a plurality of redistribution vias are vertically aligned, the above-mentioned redistribution via shape may cause stress to be concentrated at the lower portion of the lowermost redistribution via, which may cause the lowermost redistribution via to be delaminated. Further, due to the characteristics of a photolithography process, in order to form the lower portions of redistribution vias in a desired opening size, it is required to set the opening size of the upper portions of the redistribution vias to be larger than the desired opening size, which may cause an error in the overlay between the redistribution vias and redistribution lines thereon.

When an SAP is performed to form redistribution vias, it is required to perform dry etching to remove a photoimageable dielectric (PID); however, due to the limitations of the etching process, some portions may not be etched, which may cause deterioration in reliability.

Therefore, it is needed to develop a new semiconductor structure technology capable of remedying these issues.

### SUMMARY

In a semiconductor structure which includes a dielectric, first redistribution lines, redistribution vias on the first redistribution lines, and second redistribution lines on the redistribution vias, positioned in the dielectric, the redistribution vias may have width in the horizontal direction that decreases from a bottom end of the redistribution via to the top end of the redistribution via, and seed metal layers may be disposed between lower surfaces of the redistribution vias and the first redistribution lines, between side surfaces of the redistribution vias and the dielectric, and between lower surfaces of the second redistribution lines and the dielectric.

A semiconductor structure according to an embodiment may include a first redistribution line, a first redistribution via on the first redistribution line, wherein the first redistribution via has a width in a horizontal direction that decreases as it goes from a lower surface of the first redistribution via to an upper surface of the first redistribution via, a second redistribution line on the first redistribution via, a dielectric surrounding the first redistribution line, the first redistribution via, and the second redistribution line, and a first seed metal layer between a lower surface of the first redistribution via and the first redistribution line, between a side surface of the first redistribution via and the dielectric, and between the lower surface of the second redistribution line and the dielectric.

A semiconductor chip according to an embodiment may include a substrate including a front side and a back side opposite to the front side, an active layer on the front side, wherein the active layer includes an integrated circuit structure, a wiring layer on the active layer, and a back side redistribution structure on the back side of the substrate, wherein the back side redistribution structure includes: a plurality of first redistribution lines, a plurality of redistribution vias on the plurality of first redistribution lines, wherein each of plurality of redistribution vias has a width in a horizontal direction that decreases from a bottom end of each of the plurality of redistribution vias to a top end of each of the plurality of redistribution vias, a plurality of second redistribution lines on the plurality of redistribution vias, a dielectric surrounding the plurality of first redistribution lines, the plurality of redistribution vias, and the plurality of second redistribution lines, and a plurality of seed metal layers disposed between lower surfaces of the plurality of redistribution vias and the plurality of first redistribution lines between side surfaces of the plurality of redistribution vias and the dielectric, and between the dielectric and lower surfaces of the plurality of second redistribution lines.

A method for manufacturing a semiconductor structure according to an embodiment may include forming a first redistribution line and a dielectric surrounding a side surface of the first redistribution line, on a back side of a substrate, forming a first photoresist on the dielectric and the first redistribution line, patterning the first photoresist to form a first photoresist pattern on the first redistribution line, wherein the first photoresist pattern has a width in a horizontal direction that decreases from a bottom end of the first photoresist pattern to a top end of the first photoresist pattern, depositing an additional dielectric on the dielectric, the first redistribution line, and the first photoresist pattern, removing the first photoresist pattern to expose an upper surface of the first redistribution line, depositing a seed metal layer on the exposed first redistribution line and the additional dielectric, forming a second photoresist on the seed metal layer, patterning on the second photoresist to form a second photoresist pattern on the seed metal layer, the second photoresist pattern formed to expose a portion of the seed metal layer, and depositing a conductive material on the exposed a portion of the seed metal layer to form a redistribution via on the first redistribution line and to form a second redistribution line on the redistribution via.

The redistribution via shape having a width in the horizontal direction which decreases from a bottom end of the redistribution via to a top end of the redistribution via can structurally stabilize the semiconductor structure, and prevent stress from being concentrated at the lower portions of the redistribution vias to prevent the lower portions of the redistribution vias from being delaminated.

Although the upper portions of the redistribution vias have a smaller width in the horizontal direction as compared to their lower portions, since the redistribution vias and the second redistribution lines are formed integrally with each other in the process of manufacturing the semiconductor structure, it is possible to prevent the upper portions of the redistribution vias from being delaminated.

### BRIEF DESCRIPTION OF THE DRAWINGS

FIG. 1 is a cross-sectional view illustrating a first semiconductor die according to example embodiments.

FIG. 2 is a cross-sectional view illustrating region B of the first semiconductor die of FIG. 1 according to example embodiments.

FIG. 3 is a cross-sectional view illustrating a semiconductor stack structure according to example embodiments.

FIGS. 4 to 37 are cross-sectional views for explaining a method for manufacturing the first semiconductor die of FIG. 1 according to example embodiments.

### DETAILED DESCRIPTION OF THE EMBODIMENTS

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, a first semiconductor die 100, a semiconductor stack structure 10 including the first semiconductor die 100 and a second semiconductor die 200, and a method of manufacturing the first semiconductor die 100 according to example embodiments will be described with reference to the drawings.

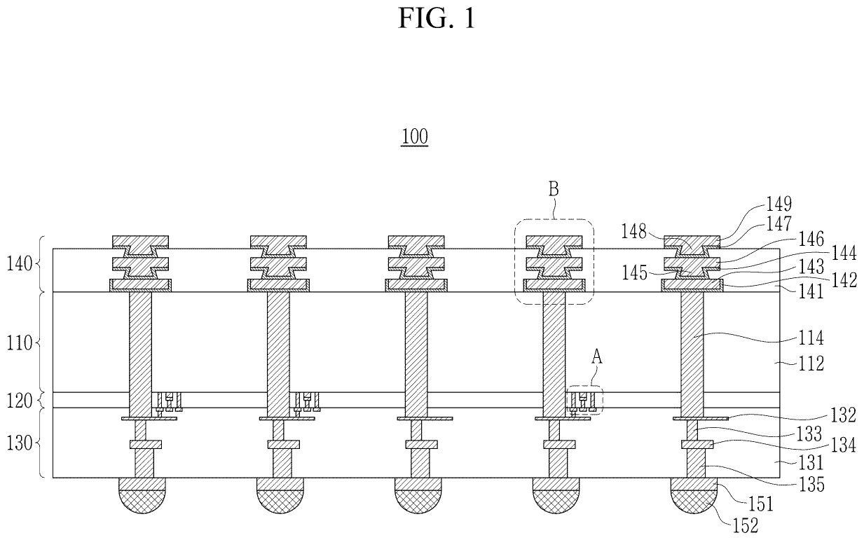

FIG. 1 is a cross-sectional view illustrating the first semiconductor die 100 according to example embodiments.

Referring to FIG. 1, the first semiconductor die 100 includes a substrate 110, an active layer 120, a wiring layer 130, through substrate vias (e.g., through silicon vias (TSVs)) 114, and a back side redistribution structure 140. In an embodiment, the first semiconductor die 100 may be a semiconductor die usable for a semiconductor stack structure such as a 3D integrated circuit (3DIC). With respect to the substrate 110, the active layer 120, the wiring layer 130, connection pads 151, and connection members 152 are disposed on the front side of the substrate 110, and the back side redistribution structure 140 is disposed on the back side of the substrate 110. The through silicon vias (TSVs) 114 pass through the substrate 110.

The substrate 110 may be a die formed from a wafer. In an embodiment, the substrate 110 may include silicon or other semiconductor materials. In an embodiment, the substrate 110 may include wells doped with impurities or structures doped with impurities. The substrate 110 may have various element isolation structures such as shallow trench isolation (STI) structures. In an embodiment, the substrate 110 may include bulk silicon, a silicon-on-insulator (SOI), silicon, silicon germanium, silicon germanium on insulator (SGOI), silicon carbide, indium antimonide, a lead tellurium compound, indium arsenide, indium phosphide, gallium arsenide, or gallium antimonide.

The active layer 120 is disposed on the front side of the substrate 110. The active layer is formed on the substrate 110 in a front-end-of-line (FEOL) process of a semiconductor manufacturing process. The active layer 120 includes integrated circuit structures A having integrated circuit regions. In an embodiment, an integrated circuit structure A may include at least one of active devices and passive devices. In an embodiment, the integrated circuit structures A may include gate structures, source regions, and drain regions. In an embodiment, an integrated circuit structure A may include at least one of transistors, diodes, capacitors, inductors, and resistors.

In an embodiment, an integrated circuit structure A may include at least one of memory devices and logic devices. The memory devices may include volatile memory devices or non-volatile memory devices. In an embodiment, the volatile memory devices may include dynamic random access memories (DRAMs), static RAMs (SRAMs), thyristor RAMs (TRAMs), zero capacitor RAMs (ZRAMs), or twin transistor RAMs (TTRAMs). In an embodiment, the non-volatile memory devices may include flash memories, magnetic RAMs (MRAMs), spin-transfer torque MRAMs (STT-MRAMs), ferroelectric RAMs (FRAMs), phase change RAMs (PRAMs), resistive RAMs (RRAMs), or the like. In an embodiment, the logic devices may include microprocessors, graphics processors, signal processors, network processors, codecs, etc.

The wiring layer 130 is disposed on the front side of the substrate 110. The wiring layer 130 is formed on the active layer 120 in a back-end-of-line (BEOL) process of the semiconductor manufacturing process. The wiring layer 130 includes wiring lines 132 and 134, contact plugs 133 and 135, and an inter metal dielectric (IMD) layer 131.

The wiring lines 132 and 134 and the contact plugs 133 and 135 are signal lines for transferring signals between individual devices and power lines for transferring power to individual devices. The wiring lines 132 and 134 are horizontally formed by patterning, and the wiring lines 132 transfer signals and power in the same level layer, and the wiring lines 134 transfer signals and power in the same level layer. The contact plugs 133 and 135 are vertically formed by patterning, so as to couple the wiring lines 132 and 134 to each other and transfer signals and power between different level layers. In an embodiment, each of the wiring lines 132 and 134 and the contact plugs 133 and 135 may include at least one of copper, aluminum, tungsten, nickel, gold, tin, titanium, and alloys thereof. In other embodiments, the wiring layer 130 may include fewer or more wiring lines and contact plugs, which are also within the scope of the present disclosure.

The inter metal dielectric (IMD) layer 131 covers and insulates the wiring lines 132 and 134 and the contact plugs 133 and 135. In an embodiment, the inter metal dielectric (IMD) layer 131 may include silicon oxide, silicon nitride, silicon oxynitride, oxide formed with TEOS, PSP, BPSG, low-k dielectric materials, other suitable dielectric materials, or combinations thereof.

The connection pads 151 are disposed on the contact plugs 135. The connection pads 151 electrically couple the contact plugs 135 to the connection members 152. The connection members 152 are disposed on the connection pads 151. The connection members 152 electrically couple the connection pads 151 to external devices. In an embodiment, the connection pads 151 may include at least one of copper, nickel, zinc, gold, silver, platinum, palladium, chromium, titanium, alloys thereof. In an embodiment, the connection members 152 may include micro bumps or solder balls. In an embodiment, the connection members 152 may include at least one of tin, silver, lead, nickel, copper, or alloys thereof.

The through silicon vias (TSVs) 114 extend from the front side of the substrate 110 to the back side of the substrate 110. The through silicon vias (TSVs) 114 are formed in the BEOL process of the semiconductor manufacturing process. In an embodiment, the through silicon vias (TSVs) 114 may extend from the inter metal dielectric (IMD) layer 131 of the wiring layer 130 into the substrate 110 through the active layer 120. In other embodiments, the through silicon vias (TSVs) 114 may extend from the active layer 120 into the substrate 110. In an embodiment, first ends of the through silicon vias (TSVs) 114 may be connected to first redistribution lines 143 of the back side redistribution structure 140, and second ends of the through silicon vias (TSVs) 114 may be connected to the wiring lines 132 of the wiring layer 130. In other embodiments, the second ends of the through silicon vias (TSVs) 114 may be connected to wiring lines of the active layer 120.

The back side redistribution structure 140 includes a dielectric 141, and the first redistribution lines 143, first redistribution vias 145, second redistribution line 146, second redistribution vias 148, first seed metal layers 142, second seed metal layers 144, and third seed metal layers 147, positioned in the dielectric 141, and bonding pads 149 disposed on the dielectric 141. In other embodiments, the back side redistribution structure 140 may include fewer or more redistribution lines, redistribution vias, seed metal layers, and bonding pads, which is also within the scope of the present disclosure.

The dielectric 141 protects and insulates the first redistribution lines 143, the first redistribution vias 145, the second redistribution lines 146, the second redistribution vias 148, the first seed metal layers 142, the second seed metal layers 144, and the third seed metal layers 147.

The first redistribution lines 143 are disposed between the through silicon vias (TSVs) 114 and the first redistribution vias 145. The first redistribution lines 143 horizontally extend so as to electrically couple the first redistribution vias 145 to the through silicon vias (TSVs) 114. The first seed metal layers 142 are interposed between the lower surfaces of the first redistribution lines 143 and an upper surface of an insulating layer 112, between the lower surfaces of the first redistribution lines 143 and upper surfaces of the through silicon vias (TSVs) 114, and between the side surfaces of first redistribution lines 143 and the dielectric 141, respectively.

The first redistribution vias 145 are disposed between the first redistribution lines 143 and the second redistribution lines 146. The first redistribution vias 145 vertically extend so as to electrically couple the second redistribution lines 146 to the first redistribution lines 143. The second seed metal layers 144 are interposed between the lower surfaces of the first redistribution vias 145 and upper surfaces of the first redistribution lines 143, between the side surfaces of the first redistribution vias 145 and the dielectric 141, and between the lower surfaces of the second redistribution lines 146 and the dielectric 141.

The second redistribution lines 146 are disposed between the first redistribution vias 145 and the second redistribution vias 148. The second redistribution lines 146 horizontally extend so as to electrically couple the second redistribution vias 148 to the first redistribution vias 145.

The second redistribution vias 148 are disposed between the second redistribution lines 146 and the bonding pads 149. The second redistribution vias 148 vertically extends so as to electrically couple the bonding pads 149 to the second redistribution lines 146. The third seed metal layers 147 are interposed between the lower surfaces of the second redistribution vias 148 and upper surfaces of the second redistribution lines 146, between the side surfaces of the second redistribution vias 148 and the dielectric 141, and between the lower surfaces of the bonding pads 149 and the dielectric 141, respectively.

In other embodiments, the back side redistribution structure 140 may include fewer or more redistribution lines, redistribution vias, seed metal layers, and bonding pads, which is also within the scope of the present disclosure.

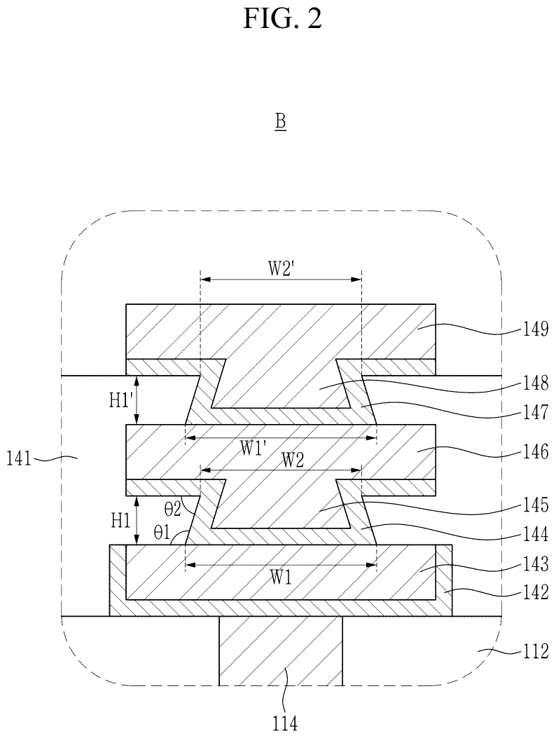

FIG. 2 is a cross-sectional view illustrating region B of the first semiconductor die 100 of FIG. 1 according to example embodiments. Since the thickness of each seed metal layer is significantly smaller than the width of each redistribution via in a horizontal direction or a height of each redistribution via in a vertical direction, in the present disclosure, as the dimensions of the redistribution vias and the redistribution lines, dimensions including the dimensions of the seed metal layers may be defined.

Referring to FIG. 2, each of the first redistribution vias 145 and the second redistribution vias 148 may have a width in the horizontal direction that decreases from a bottom end of each of the first and second redistribution vias 145 and 148 to a top end of each of the first and second redistribution vias 145 and 148. For example, a width W1 of a lower portion of the first redistribution via 145 and lower side portions of the second seed metal layer 144 between the first redistribution via 145 and the dielectric 141, in the horizontal direction may be larger than a width W2 of an upper portion of the first redistribution via 145 and upper side portions of the second seed metal layer 144 between the first redistribution via 145 and the dielectric 141, in the horizontal direction. An area of the lower portion of the first redistribution via 145 is larger than an area of an upper portion of the first redistribution via 145. For example, a width W1′ of a lower portion of the second redistribution via 148 and lower side portions of the third seed metal layer 147 between the second redistribution via 148 and the dielectric 141, in the horizontal direction may be larger than a width W2′ of an upper portion of the second redistribution via 148 and upper side portions of the third seed metal layer 147 between the second redistribution via 148 and the dielectric 141, in the horizontal direction. An area of the lower portion of the second redistribution via 148 is larger than an area of the upper portion of the second redistribution via 148. In an embodiment, the width W1 of the lowermost surface of the second seed metal layer 144 in the horizontal direction and the width W1′ of the lowermost surface of the third seed metal layer 147 in the horizontal direction may be in a range from about 8 μm to about 10 μm. In an embodiment, a height H1 may be defined from the upper surface of the first redistribution line 143 to a lower surface of the second seed metal layer 144 between the second redistribution line 146 and the dielectric 141, in a vertical direction, and a height H1′ may be defined from the upper surface of the second redistribution line 146 to a lower surface of the third seed metal layer 147 between the bonding pad 149 and the dielectric 141. In an embodiment, each of the height H1 and the height H1′ may be in a range from about 3.0 μm to about 3.5 μm. In an embodiment, an angle θ1 between the upper surface of the first redistribution line 143 (or the second redistribution line 146) and the side surface of the first redistribution via 145 (or the second redistribution via 148) may be in a range from about 100° to about 110°. In an embodiment, the angle θ1 may be defined between the upper surface of the first redistribution line 143 (or the second redistribution line 146) and the side surface of the second seed metal layer 144 (or the third seed metal layer 147). In an embodiment, an angle θ2 between a lower surface of the second redistribution line 146 (or the bonding pad 149) and the side surface of the first redistribution via 145 (or the second redistribution via 148) may be in a range from about 70° to about 80°. In an embodiment, the angle θ2 may be defined between the lower surface of the second seed metal layer 144 (or the third seed metal layer 147) contacting the dielectric 141 and the side surface of the second seed metal layer 144 (or the third seed metal layer 147).

As described above, according to the present disclosure, since each of the first redistribution vias 145 and the second redistribution vias 148 has the width in the horizontal direction which decreases as it goes from the lower side to the upper side, the first semiconductor die 100 may have a stabler structure. Further, it is possible to prevent stress from being concentrated at the lower portions of the first redistribution vias 145 and the second redistribution vias 148, thereby preventing the lower surfaces of the first redistribution vias 145 from be delaminated from the first redistribution lines 143 and preventing the lower surfaces of the second redistribution vias 148 from being delaminated from the second redistribution lines 146.

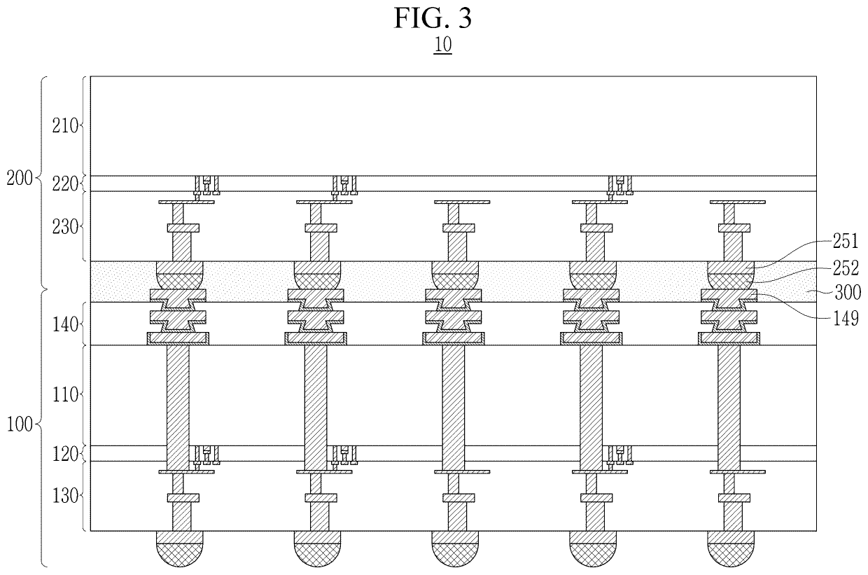

FIG. 3 is a cross-sectional view illustrating the semiconductor stack structure 10 according to example embodiments.

Referring to FIG. 3, the semiconductor stack structure 10 includes the first semiconductor die 100 and the second semiconductor die 200. The semiconductor stack structure 10 may have a structure in which different types of dies are stacked. In an embodiment, the first semiconductor die 100 and the second semiconductor die 200 may be different types of dies. In an embodiment, the semiconductor stack structure 10 may include a system on chip (SoC). In an embodiment, the semiconductor stack structure 10 may include a three-dimensional integrated circuit (3DIC). In an embodiment, the first semiconductor die 100 may be a lower die of the 3D integrated circuit. In an embodiment, the second semiconductor die 200 may be an upper die of the 3D integrated circuit. In an embodiment, the first semiconductor die 100 may include a central processing unit (CPU) or a graphic processing unit (GPU). In an embodiment, the first semiconductor die 100 may include a buffer chip. In an embodiment, the second semiconductor die 200 may include at least one of memories, communication chips, controllers, and sensors.

In an embodiment, the second semiconductor die 200 may include a substrate 210, an active layer 220 and a wiring layer 230. For example, the substrate 210, the active layer 220 and the wiring layer 230 of the second semiconductor die 200 may correspond to the substrate 110, the active layer 120 and the wiring layer 130 of the first semiconductor die 100.

The bonding pads 149 of the first semiconductor die 100 and connection members 252 of the second semiconductor die 200 are bonded, whereby the first semiconductor die 100 and the second semiconductor die 200 are electrically connected. Between the first semiconductor die 100 and the second semiconductor die 200, an insulating member 300 is provided so as to cover and protect connection pads 251, the connection members 252, and the bonding pads 149. In an embodiment, the insulating member 300 may include a non-conductive film (NCF). In an embodiment, the insulating member 300 may include molded underfill (MUF).

In an embodiment, a wafer including a plurality of first semiconductor dies 100 and a wafer including a plurality of second semiconductor dies 200 may be electrically connected to each other in a semiconductor manufacturing process. In an embodiment, a plurality of first semiconductor dies 100 formed from a wafer and a wafer including a plurality of second semiconductor dies 200 may be electrically connected to each other in a semiconductor manufacturing process. In an embodiment, a wafer including a plurality of first semiconductor dies 100 and a plurality of second semiconductor dies 200 formed from a wafer may be electrically connected to each other in a semiconductor manufacturing process.

In an embodiment, the second semiconductor die 200 may not include through silicon vias extending from the front side of the substrate to the back side of the substrate. In an embodiment, the second semiconductor die 200 may not include a back side redistribution structure. With respect to the structure of the second semiconductor die 200 other than the above-mentioned contents, the contents described with respect to the first semiconductor die 100 may be applied.

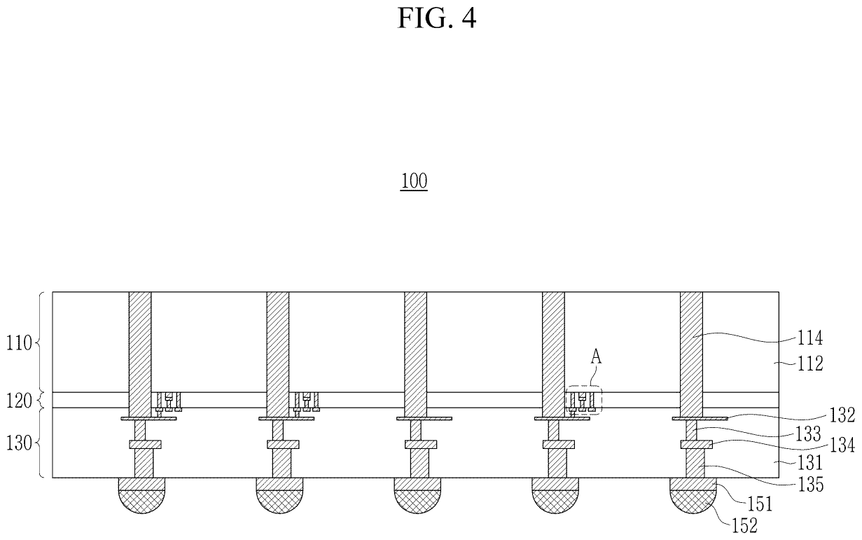

FIGS. 4 to 37 are cross-sectional views for explaining a method for manufacturing the first semiconductor die 100 of FIG. 1 according to example embodiments.

FIG. 4 is a cross-sectional view illustrating a step of providing the first semiconductor die 100 having the through silicon vias (TSVs) 114.

Referring to FIG. 4, it is provided the first semiconductor die 100 having the active layer 120 and the wiring layer 130 formed on the front side of the substrate 110 in the semiconductor front end process of the semiconductor manufacturing process and having the through silicon vias (TSVs) 114 formed so as to extend from the front side of the substrate 110 to the back side of the substrate 110 in the semiconductor front end process of the semiconductor manufacturing process.

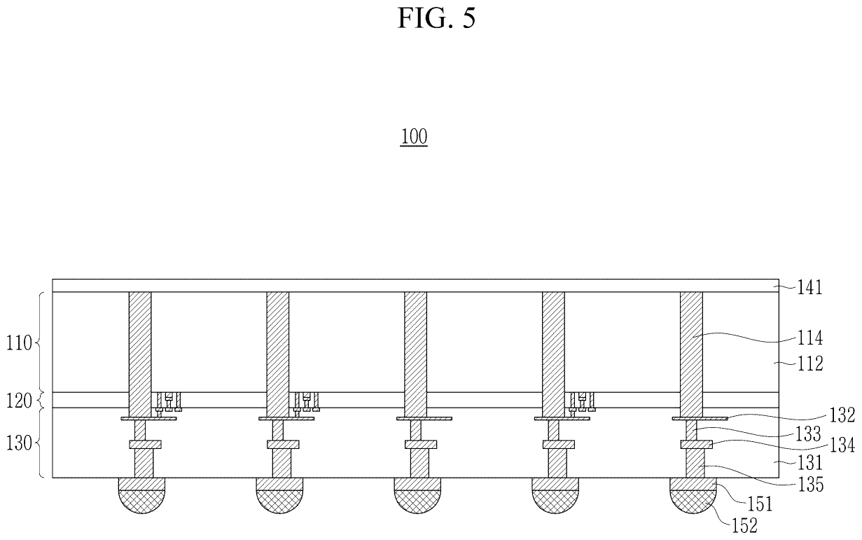

FIG. 5 is a cross-sectional view illustrating a step of forming the dielectric 141 on the back side of the substrate 110.

Referring to FIG. 5, on the back side of the substrate 110 and on the exposed surfaces of the through silicon vias (TSVs) 114, the dielectric 141 is deposited. In an embodiment, the dielectric 141 may include photoimageable dielectric (PID) (a photosensitive dielectric) which is used in a redistribution process. The photoimageable dielectric is a material applied to a photolithography process to form fine patterns. As an embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an embodiment, the dielectric 141 may be formed through spin coating.

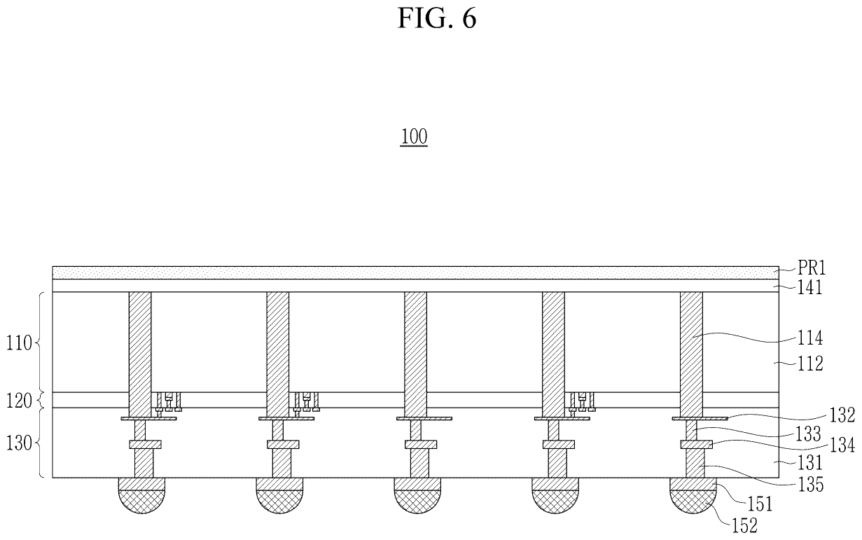

FIG. 6 is a cross-sectional view illustrating a step of depositing a first photoresist PR1 on the dielectric 141.

Referring to FIG. 6, the first photoresist PR1 is deposited on the dielectric 141. In an embodiment, the first photoresist PR1 may be deposited by spin coating. In an embodiment, the first photoresist PR1 may include an organic polymer resin comprising a photoactive material.

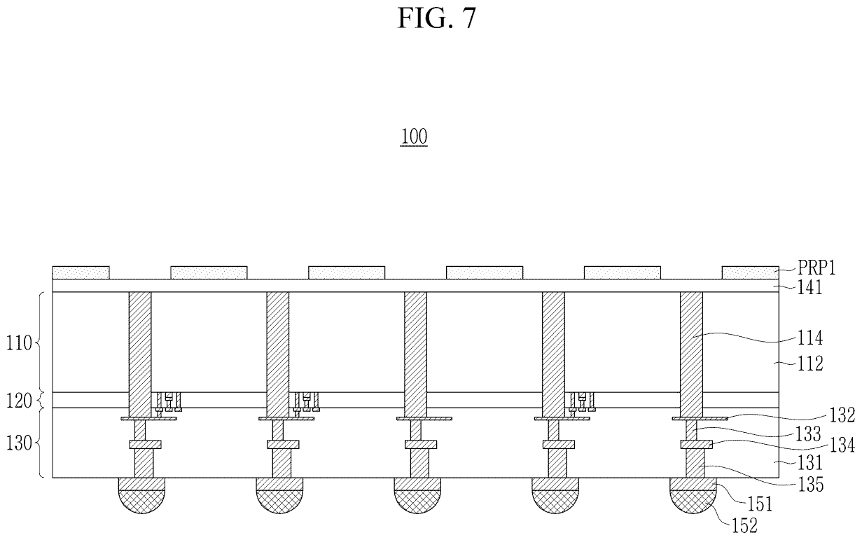

FIG. 7 is a cross-sectional view illustrating a step of forming first photoresist patterns PRP1 by performing exposing and developing on the first photoresist PR1.

Referring to FIG. 7, the first photoresist patterns PRP1 are formed by performing exposing and developing on the first photoresist PR1.

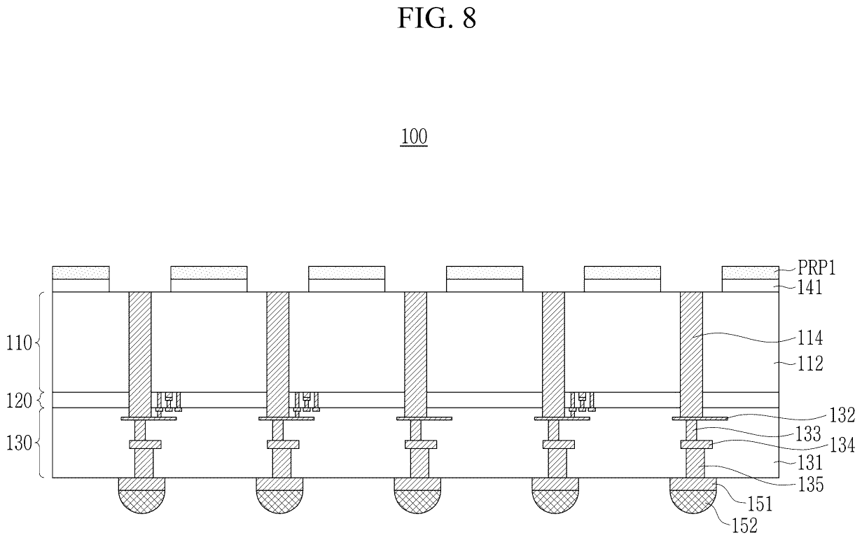

FIG. 8 is a cross-sectional view illustrating a step of exposing the upper surfaces of the through silicon vias (TSVs) 114 by patterning the dielectric 141.

Referring to FIG. 8, the portions of the dielectric 141 exposed from the first photoresist patterns PRP1 are etched such that the upper surfaces of the through silicon vias (TSVs) 114 are exposed.

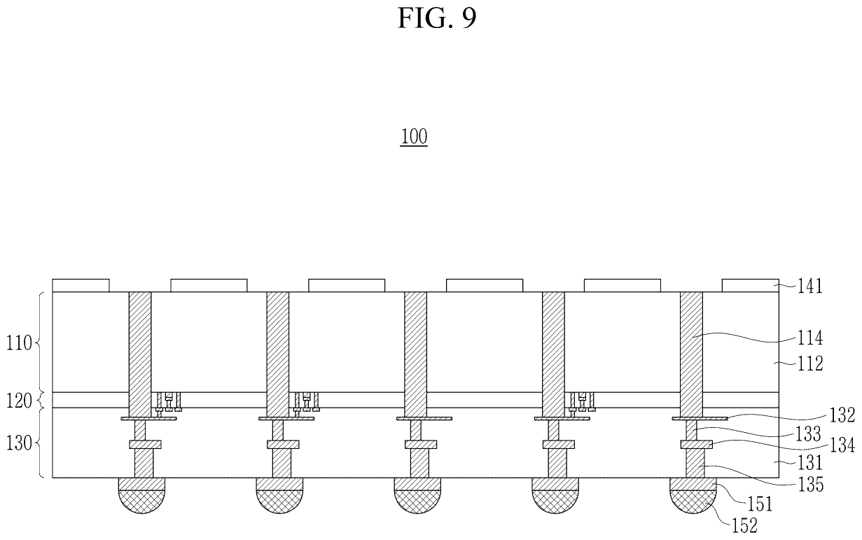

FIG. 9 is a cross-sectional view illustrating a step of removing the first photoresist patterns PRP1.

Referring to FIG. 9, the first photoresist patterns PRP1 are removed. In an embodiment, the first photoresist patterns PRP1 may be removed by at least one of etching, ashing, and stripping.

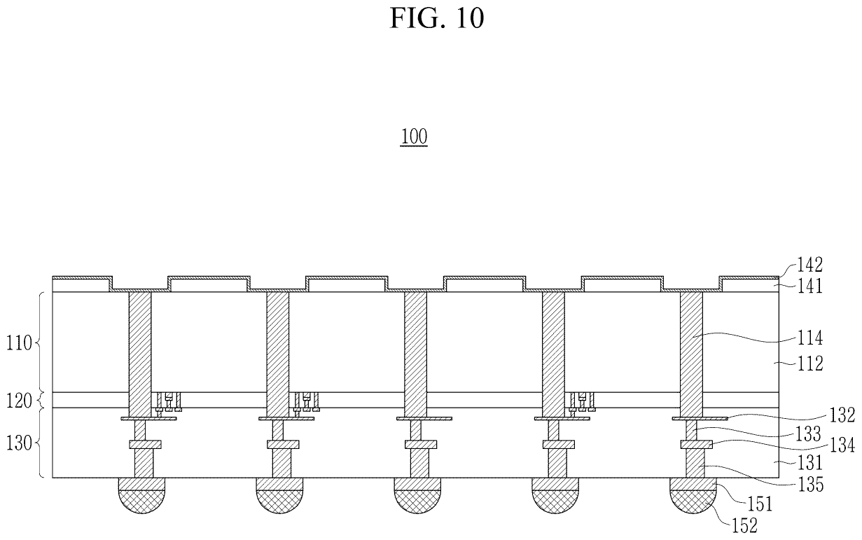

FIG. 10 is a cross-sectional view illustrating a step of depositing a first seed metal layer 142.

Referring to FIG. 10, the first seed metal layer 142 is conformally deposited on the back side of the substrate 110, the exposed upper surfaces of the through silicon vias (TSVs) 114, and the surface of the dielectric 141. In an embodiment, the first seed metal layer 142 may include copper. In an embodiment, the first seed metal layer 142 may include a conductive material usable for electroplating. In an embodiment, the first seed metal layer 142 may be formed by electroless plating. In an embodiment, prior to the electroless plating, a cleaning process or a metal catalyst activation pretreatment process may be performed. In other embodiments, the first seed metal layer 142 may be formed by sputtering.

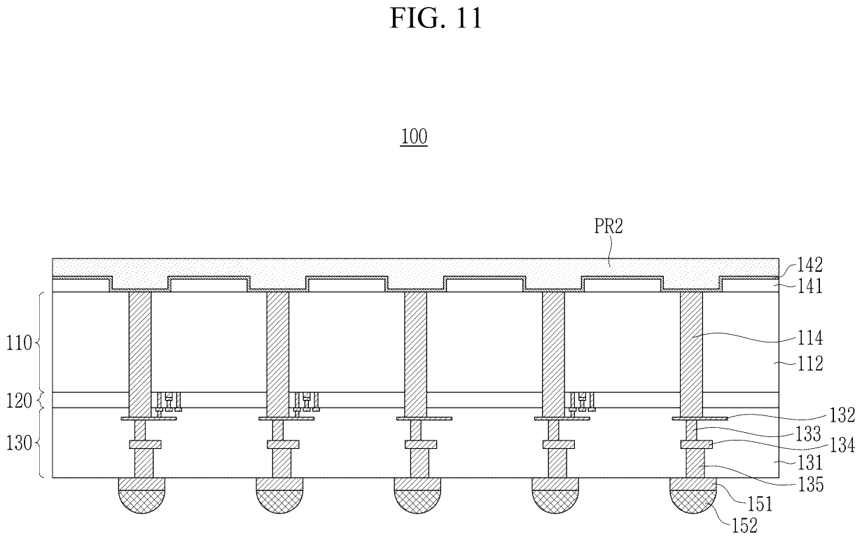

FIG. 11 is a cross-sectional view illustrating a step of depositing a second photoresist PR2 on the first seed metal layer 142.

Referring to FIG. 11, the second photoresist PR2 is deposited on the first seed metal layer 142. In an embodiment, the second photoresist PR2 may be deposited by spin coating. In an embodiment, the second photoresist PR2 may include an organic polymer resin comprising a photoactive material.

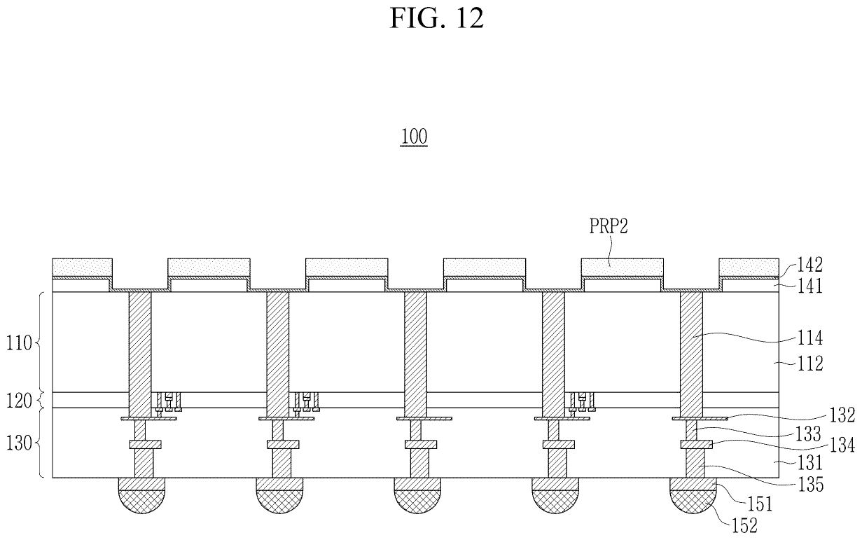

FIG. 12 is a cross-sectional view illustrating a step of forming second photoresist patterns PRP2 by performing exposing and developing on the second photoresist PR2.

Referring to FIG. 12, the second photoresist patterns PRP2 are formed by performing exposing and developing on the second photoresist PR2, such that the openings between the second photoresist patterns PRP2 expose the first seed metal layer 142.

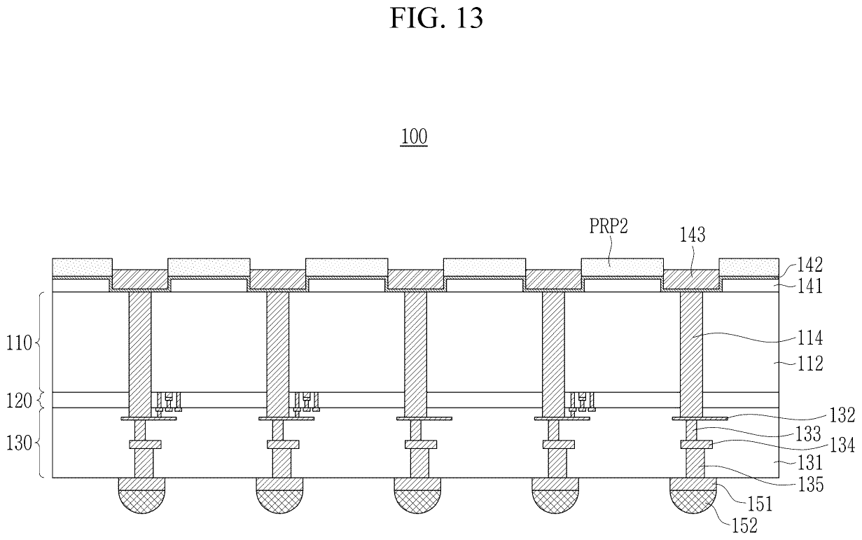

Referring to FIG. 13, on the portions of the first seed metal layer 142 exposed between the second photoresist patterns PRP2, the first redistribution lines 143 are deposited. In an embodiment, the step of depositing the first redistribution lines 143 may be performed by electroplating. The first redistribution lines 143 are formed by growing metal layers from the previously formed first seed metal layer 142 by electroplating. In an embodiment, after the first redistribution lines 143 are formed, an annealing process may be performed. In an embodiment, the first redistribution lines 143 may include copper. In other embodiments, the first redistribution lines 143 may include a conductive material usable for electroplating.

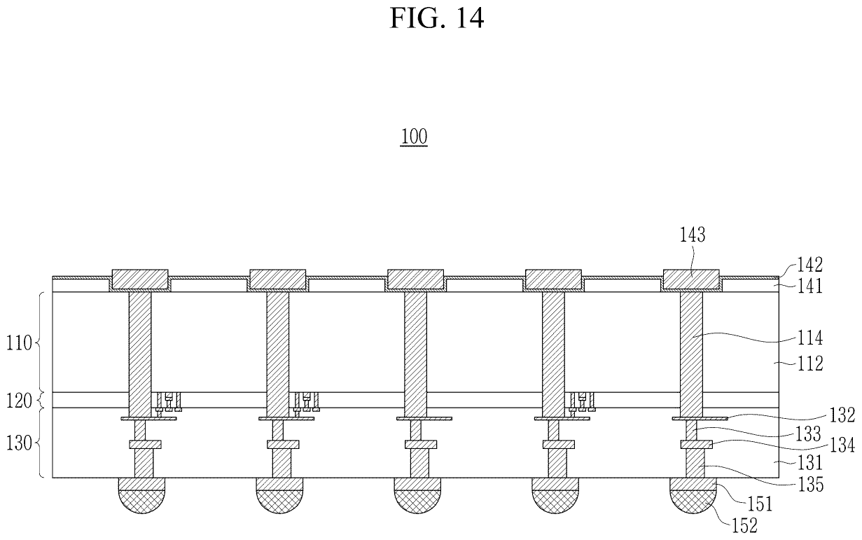

FIG. 14 is a cross-sectional view illustrating a step of removing the second photoresist patterns PRP2.

Referring to FIG. 14, the second photoresist patterns PRP2 are removed. In an embodiment, the second photoresist patterns PRP2 may be removed by at least one of etching, ashing, and stripping.

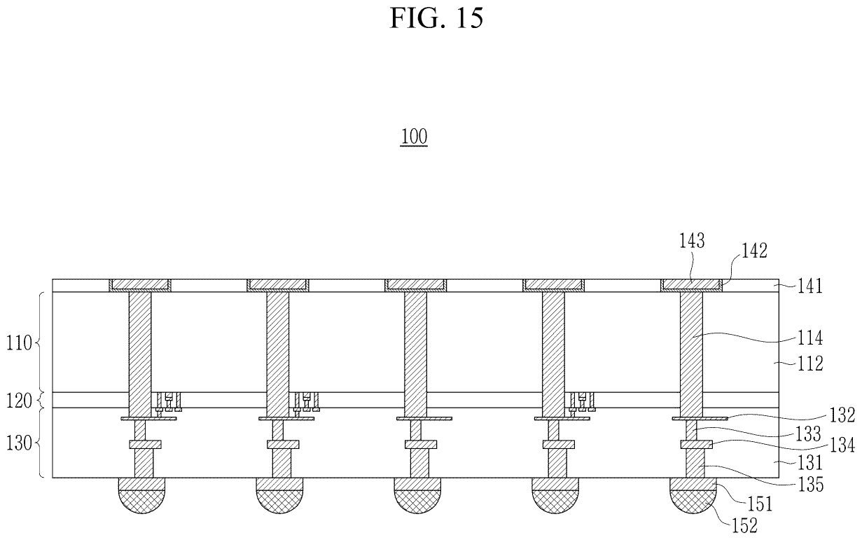

FIG. 15 is a cross-sectional view illustrating a step of performing a chemical mechanical polishing (CMP) process on the first seed metal layer 142 and the first redistribution lines 143.

Referring to FIG. 15, the chemical mechanical polishing (CMP) process is performed on the portions of the first seed metal layer 142 positioned on an upper surface of the dielectric 141 and some portions of the first redistribution lines 143 such that the upper surface of the dielectric 141 and the upper surfaces of the first redistribution lines 143 are leveled with each other. After the chemical mechanical polishing (CMP) process is performed, the upper surface of the dielectric 141 and the upper surfaces of the first redistribution lines 143 are exposed.

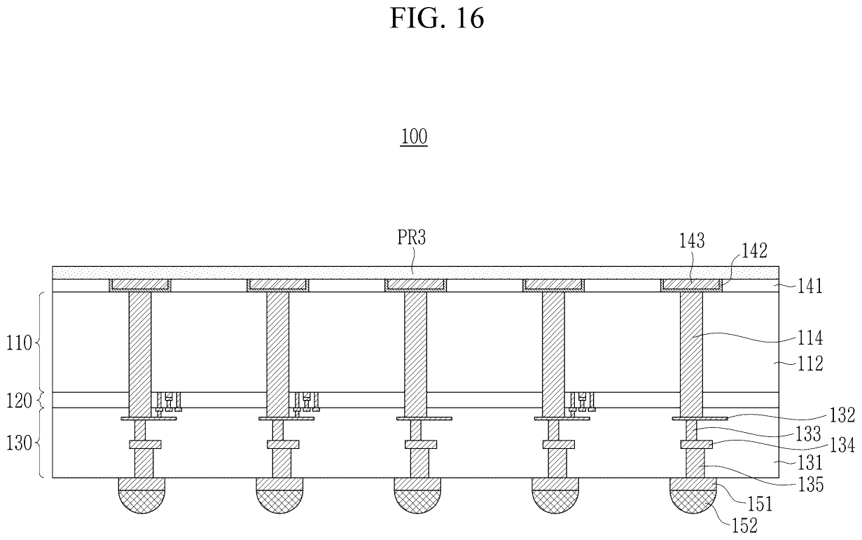

FIG. 16 is a cross-sectional view illustrating a step of depositing a third photoresist PR3 to the upper surface of the dielectric 141 and the upper surfaces of the first redistribution lines 143.

Referring to FIG. 16, the third photoresist PR3 is deposited on the upper surface of the dielectric 141 and the upper surfaces of the first redistribution lines 143. In an embodiment, the third photoresist PR3 may be deposited by spin coating. In an embodiment, the third photoresist PR3 may include an organic polymer resin comprising a photoactive material.

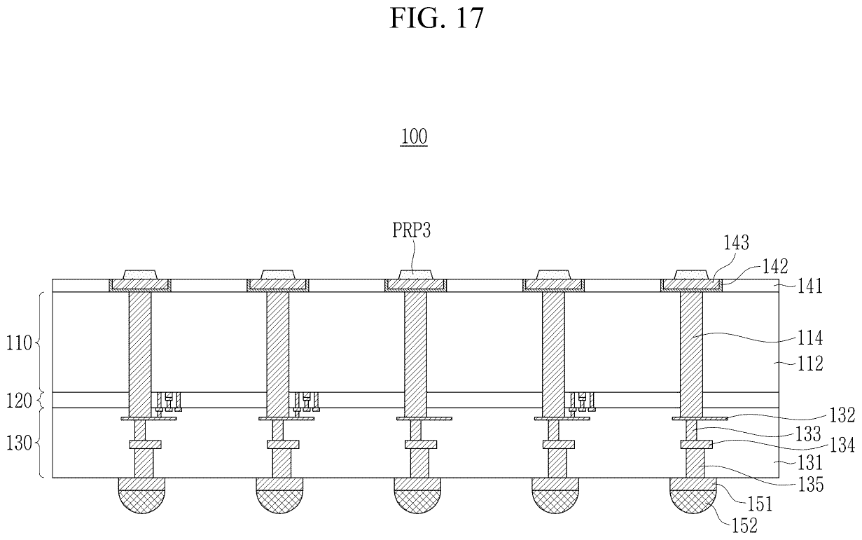

FIG. 17 is a cross-sectional view illustrating a step of forming third photoresist patterns PRP3 by performing exposing and developing on the third photoresist PR3.

Referring to FIG. 17, the third photoresist patterns PRP3 are formed by performing exposing and developing on the third photoresist PR3. In an embodiment, the cross-sectional shapes of the third photoresist patterns PRP3 in the horizontal direction may include a trapezoid shape, a circular shape, an oval shape, a rectangular shape, or a hexagonal shape. In an embodiment, each third photoresist pattern PRP3 may have a width in the horizontal direction which decreases as it goes from the lower side to the upper side.

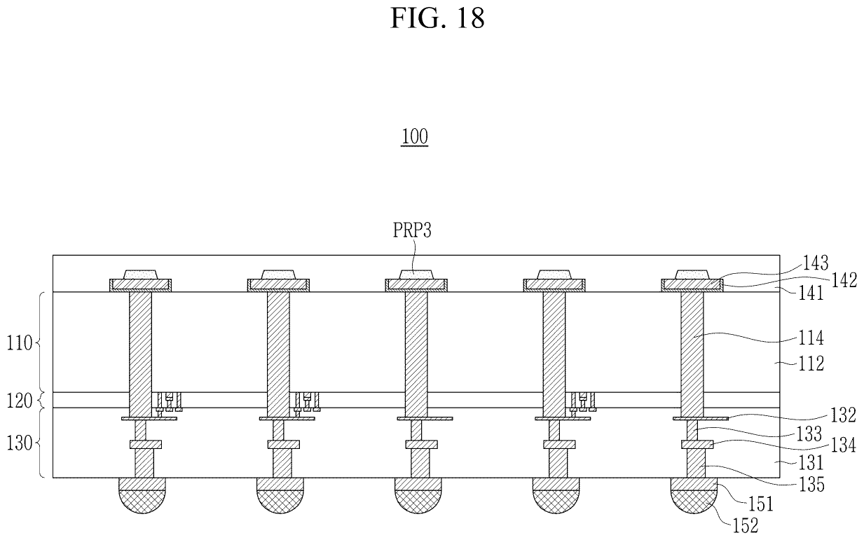

FIG. 18 is a cross-sectional view illustrating a step of additionally forming another dielectric 141 on the formed dielectric 141, on the first redistribution lines 143 exposed from the third photoresist patterns PRP3 and on the third photoresist patterns PRP3.

Referring to FIG. 18, another dielectric 141 is additionally deposited on the first redistribution lines 143 exposed from the third photoresist patterns PRP3 and the third photoresist patterns PRP3. As for features of the additional dielectric 141, the features of the dielectric 141 described with respect to FIG. 5 are applied.

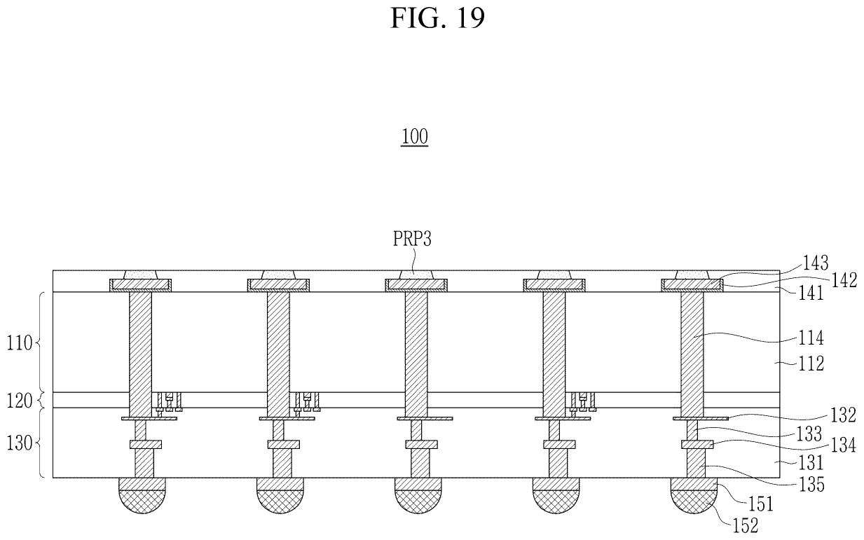

FIG. 19 is a cross-sectional view illustrating a step of performing a chemical mechanical polishing (CMP) process on the dielectric 141.

Referring to FIG. 19, the chemical mechanical polishing (CMP) process is performed on the dielectric 141 such that the upper surface of the dielectric 141 and upper surfaces of the third photoresist patterns PRP3 are leveled with each other. After the chemical mechanical polishing (CMP) process is performed, the upper surfaces of the third photoresist patterns PRP3 are exposed.

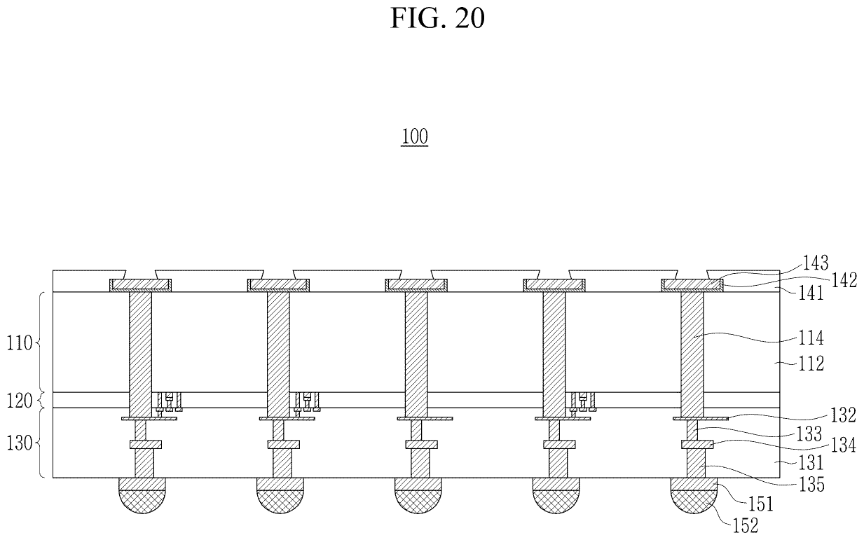

FIG. 20 is a cross-sectional view illustrating a step of removing the third photoresist patterns PRP3.

Referring to FIG. 20, the third photoresist patterns PRP3 are removed. In an embodiment, the third photoresist patterns PRP3 may be removed by at least one of etching, ashing, and stripping.

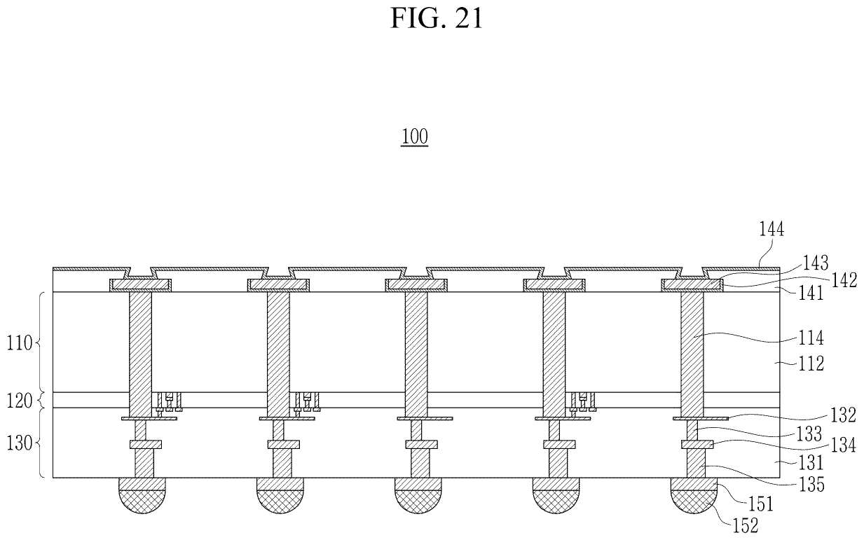

FIG. 21 is a cross-sectional view illustrating a step of depositing a second seed metal layer 144.

Referring to FIG. 21, the second seed metal layer 144 is conformally deposited on the exposed upper surfaces of the first redistribution lines 143 and the surface of the dielectric 141. In an embodiment, the second seed metal layer 144 may include copper. In an embodiment, the second seed metal layer 144 may include a conductive material usable for electroplating. In an embodiment, the second seed metal layer 144 may be formed by electroless plating. In an embodiment, prior to the electroless plating, a cleaning process or a metal catalyst activation pretreatment process may be performed.

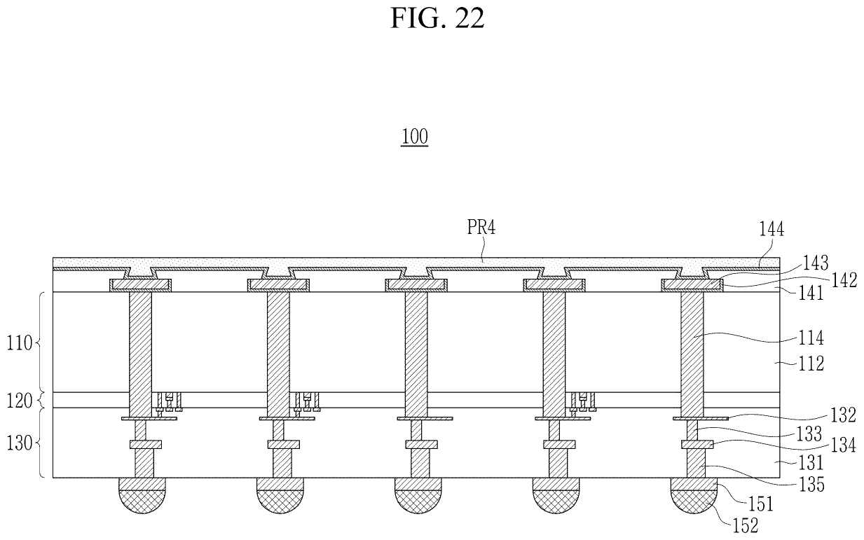

FIG. 22 is a cross-sectional view illustrating a step of forming a fourth photoresist PR4 on the second seed metal layer 144.

Referring to FIG. 22, the fourth photoresist PR4 is deposited on the second seed metal layer 144. In an embodiment, the fourth photoresist PR4 may be deposited by spin coating. In an embodiment, the fourth photoresist PR4 may include an organic polymer resin comprising a photoactive material.

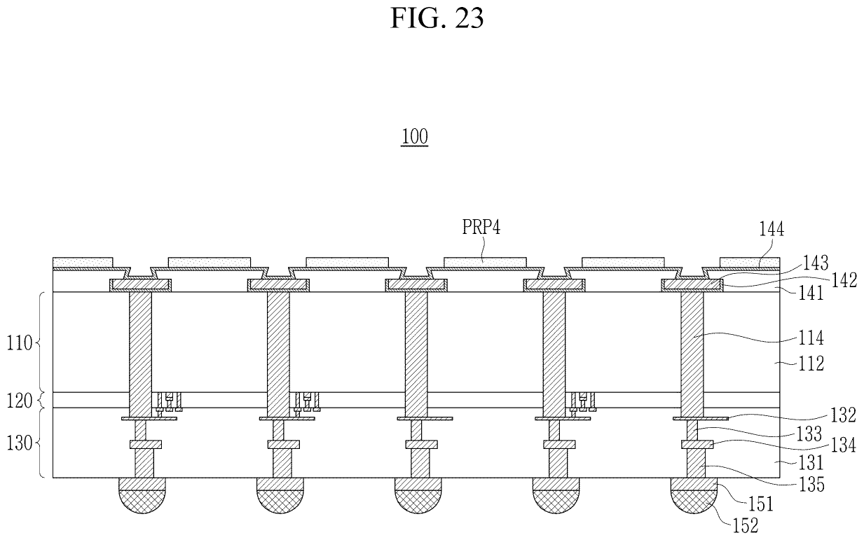

FIG. 23 is a cross-sectional view illustrating a step of forming fourth photoresist patterns PRP4 by performing exposing and developing on the fourth photoresist PR4.

Referring to FIG. 23, the fourth photoresist patterns PRP4 are formed by performing exposing and developing on the fourth photoresist PR4.

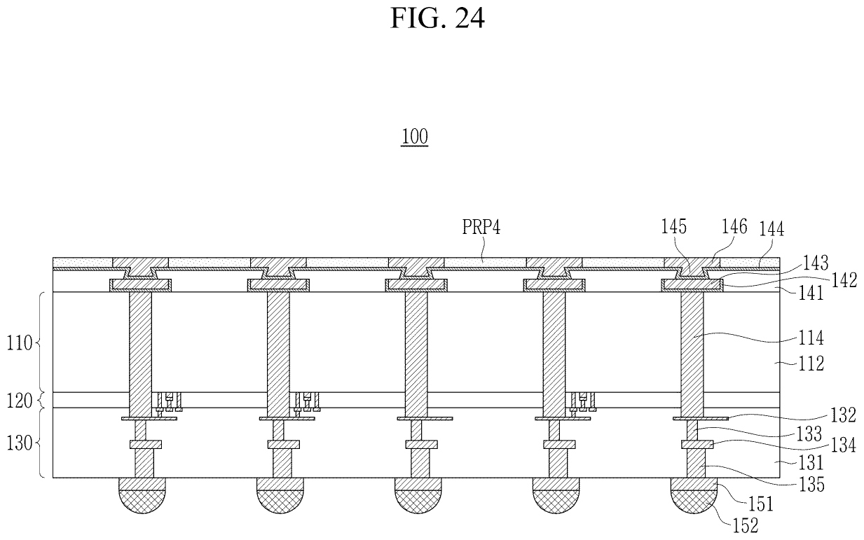

Referring to FIG. 24, on the portions of the second seed metal layer 144 exposed between the fourth photoresist patterns PRP4, the first redistribution vias 145 and the second redistribution lines 146 are deposited. In an embodiment, the process of depositing the first redistribution vias 145 and the second redistribution lines 146 may be performed by electroplating. The first redistribution vias 145 and the second redistribution lines 146 are formed by growing metal layers from the previously formed second seed metal layer 144 by electroplating. The first redistribution vias 145 and the second redistribution lines 146 are formed integrally with each other by a single process. In an embodiment, after the first redistribution vias 145 and the second redistribution lines 146 are formed, an annealing process may be performed. In an embodiment, each of the first redistribution vias 145 and the second redistribution lines 146 may include copper. In other embodiments, each of the first redistribution vias 145 and the second redistribution lines 146 may include a conductive material usable for electroplating. In an embodiment, the cross-sectional shapes of the first redistribution vias 145 in the horizontal direction after the electroplating may include a trapezoid shape, a circular shape, an oval shape, a rectangular shape, or a hexagonal shape.

According to the present disclosure, although the width of the upper portions of each of the first redistribution vias 145 in the horizontal direction is smaller than that of its lower portion, since the first redistribution vias 145 and the second redistribution lines 146 are formed integrally with each other, it is possible to prevent the upper portions of the first redistribution vias 145 from being delaminated.

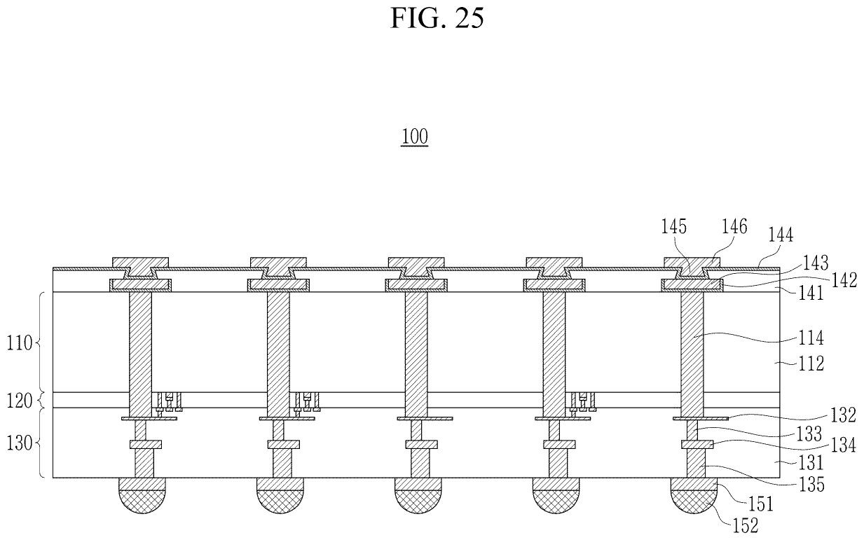

FIG. 25 is a cross-sectional view illustrating a step of removing the fourth photoresist patterns PRP4.

Referring to FIG. 25, the fourth photoresist patterns PRP4 are removed. In an embodiment, the fourth photoresist patterns PRP4 may be removed by at least one of etching, ashing, and stripping.

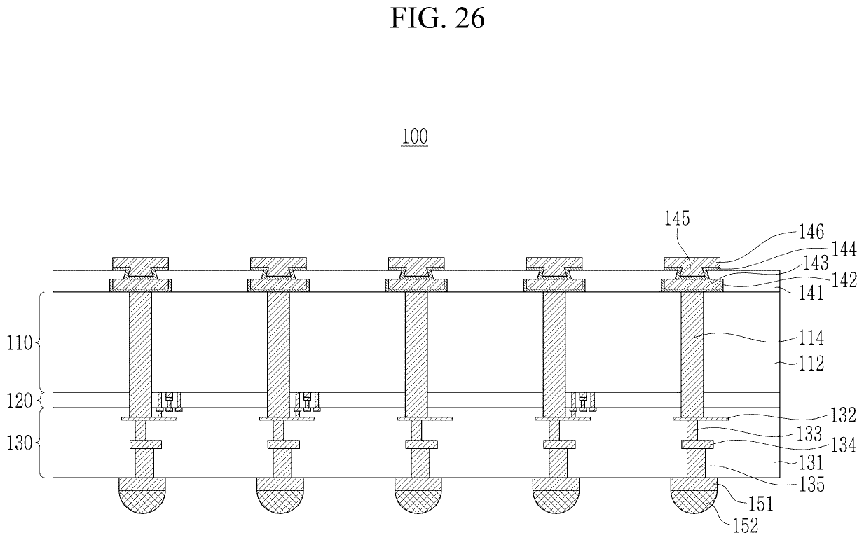

FIG. 26 is a cross-sectional view illustrating a step of removing the exposed portions of the second seed metal layer 144.

Referring to FIG. 26, the exposed portions of the second seed metal layer 144 are etched.

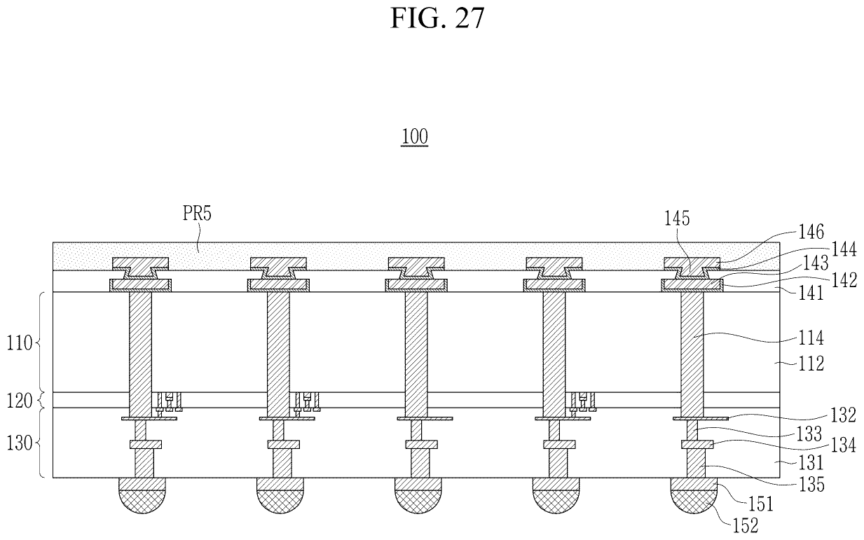

FIG. 27 is a cross-sectional view illustrating a step of depositing a fifth photoresist PR5 on the dielectric 141 and the second redistribution lines 146.

Referring to FIG. 27, the fifth photoresist PR5 is deposited on the dielectric 141 and the second redistribution lines 146. In an embodiment, the fifth photoresist PR5 may be deposited by spin coating. In an embodiment, the fifth photoresist PR5 may include an organic polymer resin comprising a photoactive material.

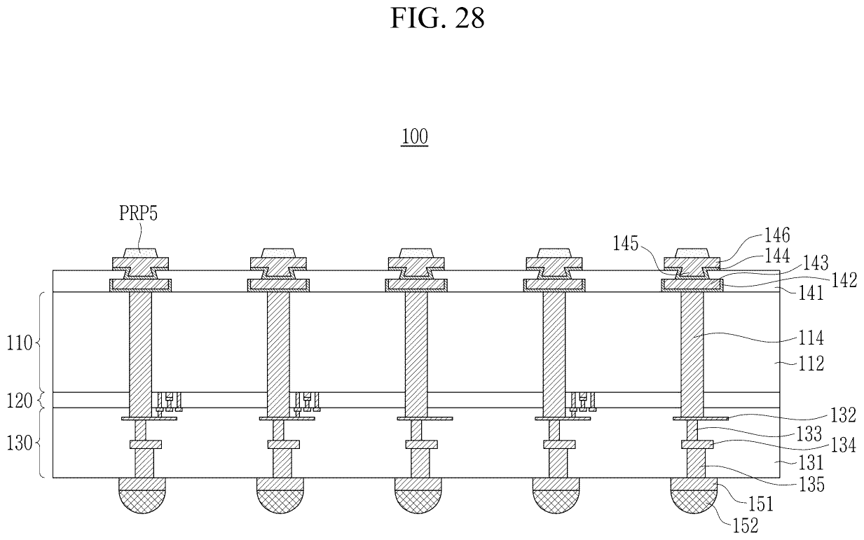

FIG. 28 is a cross-sectional view illustrating a step of forming fifth photoresist patterns PRP5 by performing exposing and developing on the fifth photoresist PR5.

Referring to FIG. 28, the fifth photoresist patterns PRP5 are formed by performing exposing and developing on the fifth photoresist PR5. In an embodiment, the cross-sectional shapes of the fifth photoresist patterns PRP5 in the horizontal direction may include a trapezoid shape, a circular shape, an oval shape, a rectangular shape, or a hexagonal shape. In an embodiment, each fifth photoresist pattern PRP5 may have a width in the horizontal direction that decreases from a bottom end of the fifth photoresist pattern PRP5 to a top end of the fifth photoresist pattern PRP5.

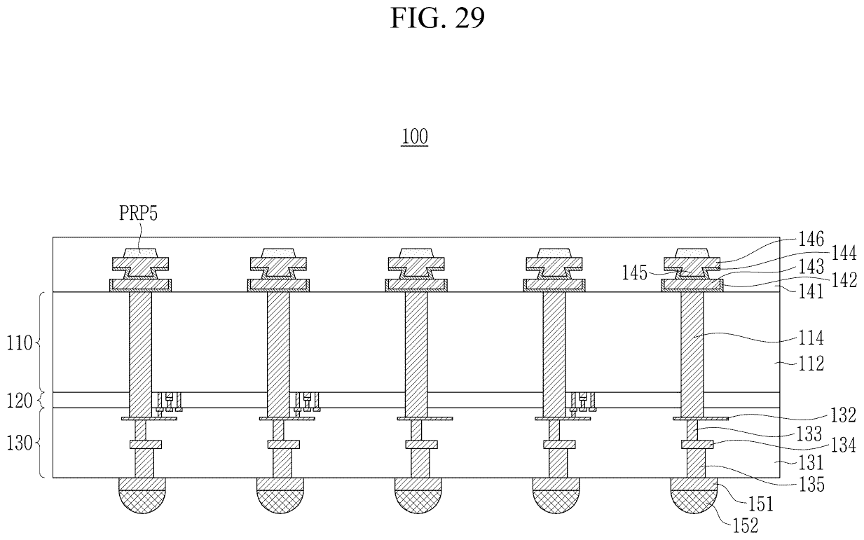

FIG. 29 is a cross-sectional view illustrating a step of additionally forming another dielectric 141 on the formed dielectric 141, the second redistribution lines 146 exposed from the fifth photoresist patterns PRP5, and the fifth photoresist patterns PRP5.

Referring to FIG. 29, another dielectric 141 is deposited on the formed dielectric 141, the second redistribution lines 146 exposed from the fifth photoresist patterns PRP5, and the fifth photoresist patterns PRP5. As for features of the additional dielectric 141, the features of the dielectric 141 described with respect to FIG. 5 are applied.

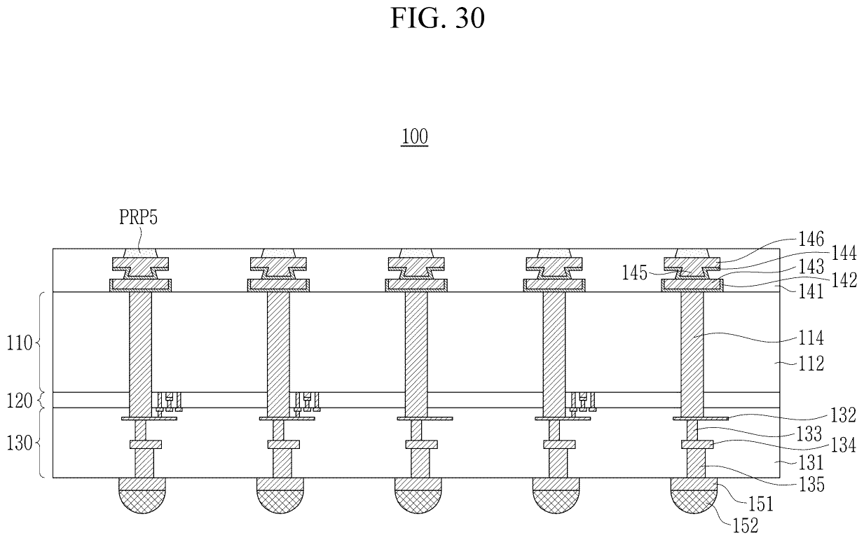

FIG. 30 is a cross-sectional view illustrating a step of performing a chemical mechanical polishing (CMP) process on the dielectric 141.

Referring to FIG. 30, the chemical mechanical polishing (CMP) process is performed on the dielectric 141 such that the upper surface of the dielectric 141 and upper surfaces of the fifth photoresist patterns PRP5 are leveled with each other. After the chemical mechanical polishing (CMP) process is performed, the upper surfaces of the fifth photoresist patterns PRP5 are exposed.

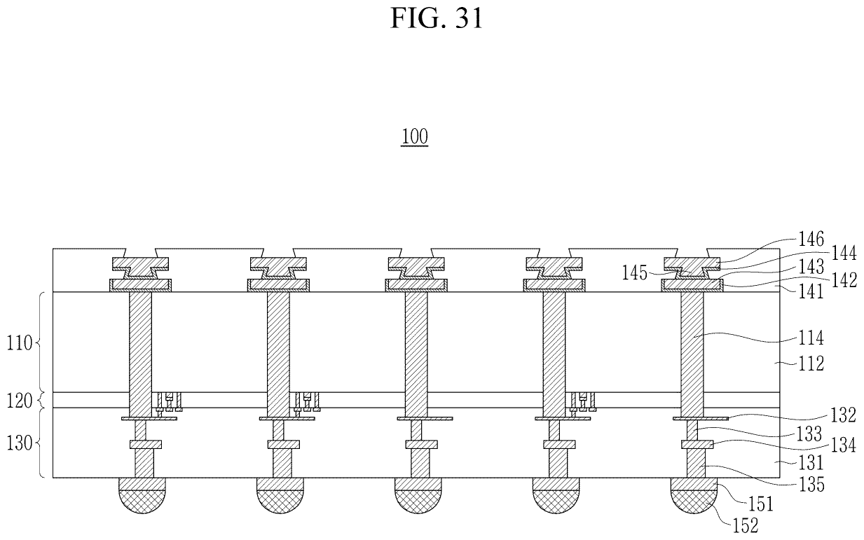

FIG. 31 is a cross-sectional view illustrating a step of removing the fifth photoresist patterns PRP5.

Referring to FIG. 31, the fifth photoresist patterns PRP5 are removed. In an embodiment, the fifth photoresist patterns PRP5 may be removed by at least one of etching, ashing, and stripping.

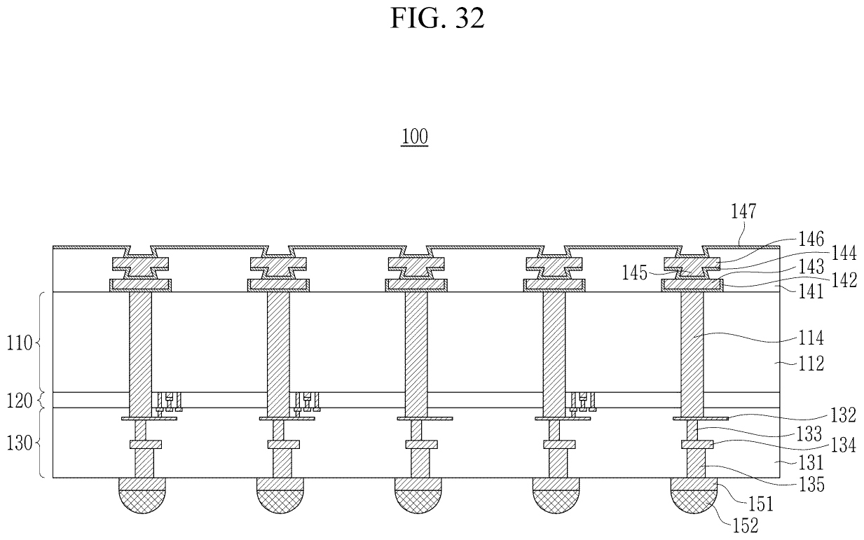

FIG. 32 is a cross-sectional view illustrating a step of depositing a third seed metal layer 147.

Referring to FIG. 32, the third seed metal layer 147 is conformally deposited on the exposed upper surfaces of the second redistribution lines 146 and the surface of the dielectric 141. In an embodiment, the third seed metal layer 147 may include copper. In an embodiment, the third seed metal layer 147 may include a conductive material usable for electroplating. In an embodiment, the third seed metal layer 147 may be formed by electroless plating. In an embodiment, prior to the electroless plating, a cleaning process or a metal catalyst activation pretreatment process may be performed.

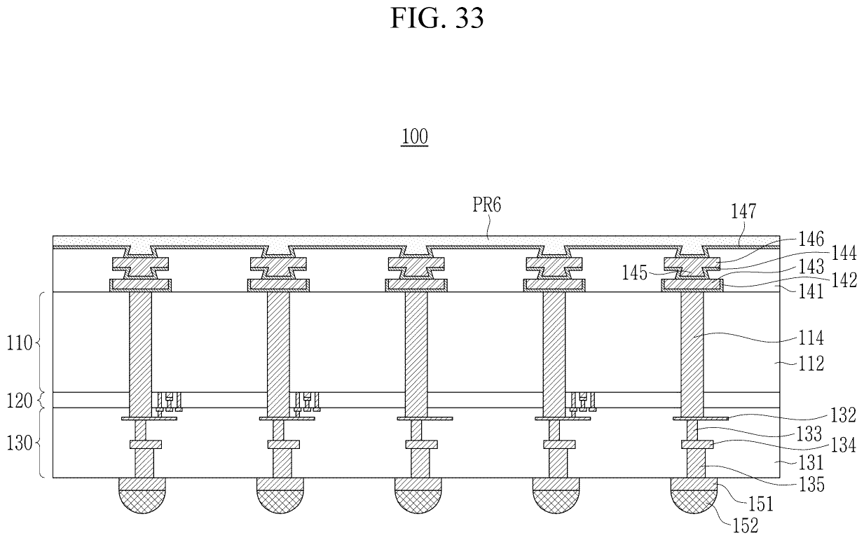

FIG. 33 is a cross-sectional view illustrating a step of depositing a sixth photoresist PR6 on the third seed metal layer 147.

Referring to FIG. 33, the sixth photoresist PR6 is deposited on the third seed metal layer 147. In an embodiment, the sixth photoresist PR6 may be deposited by spin coating. In an embodiment, the sixth photoresist PR6 may include an organic polymer resin comprising a photoactive material.

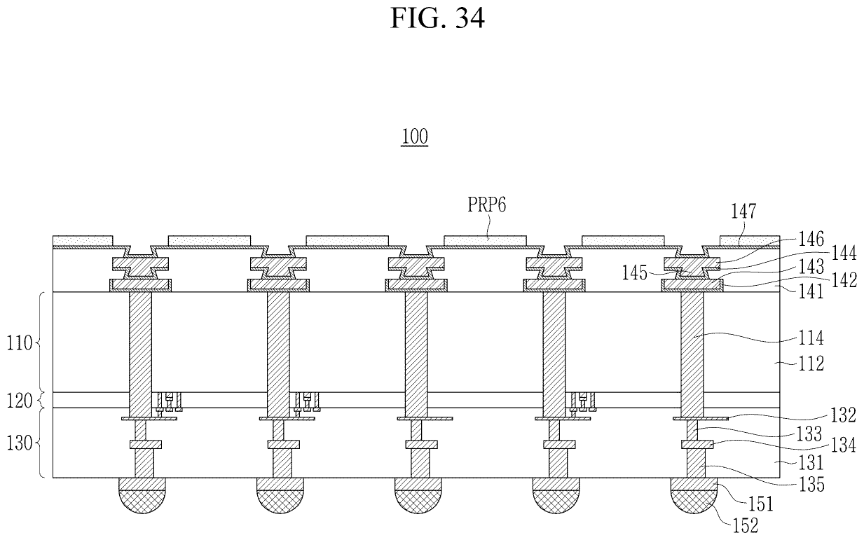

FIG. 34 is a cross-sectional view illustrating a step of forming sixth photoresist patterns PRP6 by performing exposing and developing on the sixth photoresist PR6.

Referring to FIG. 34, the sixth photoresist patterns PRP6 are formed by performing exposing and developing on the sixth photoresist PR6.

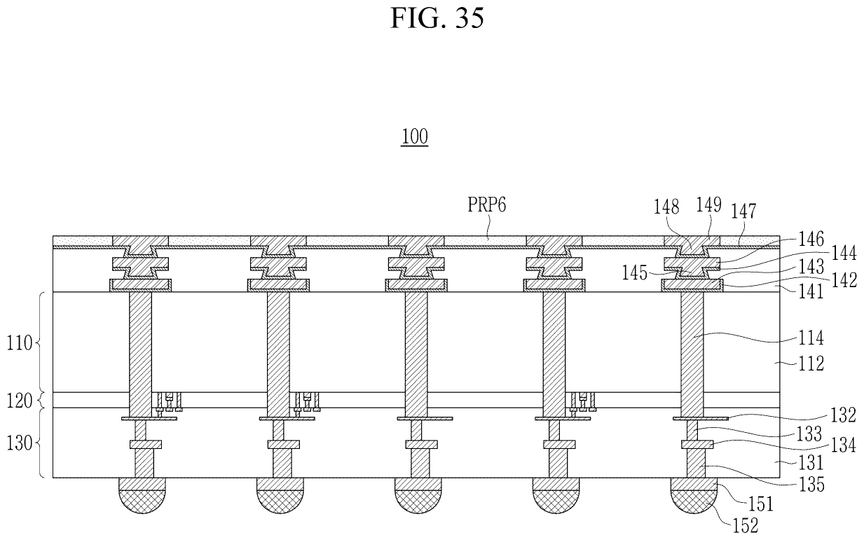

Referring to FIG. 35, on the portions of the third seed metal layer 147 exposed between the sixth photoresist patterns PRP6, the second redistribution vias 148 and the bonding pads 149 are deposited. In an embodiment, the process of depositing the second redistribution vias 148 and the bonding pads 149 may be performed by electroplating. The second redistribution vias 148 and the bonding pads 149 are formed by growing metal layers from the previously formed third seed metal layer 147 by electroplating. The second redistribution vias 148 and the bonding pads 149 are formed integrally with each other by a single process. In an embodiment, after the second redistribution vias 148 and the bonding pads 149 are formed, an annealing process may be performed. In an embodiment, each of the second redistribution vias 148 and the bonding pads 149 may include copper. In other embodiments, each of the redistribution vias 148 and the bonding pads 149 may include a conductive material usable for electroplating. In an embodiment, the cross-sectional shapes of second redistribution vias 148 in the horizontal direction after the electroplating may include a trapezoid shape, a circular shape, an oval shape, a rectangular shape, or a hexagonal shape.

According to the present disclosure, although the width of the upper portion of each of the second redistribution vias 148 is smaller than that of its lower portion, since the second redistribution vias 148 and the bonding pads 149 are formed integrally with each other, it is possible to prevent the upper portions of the second redistribution vias 148 from being delaminated.

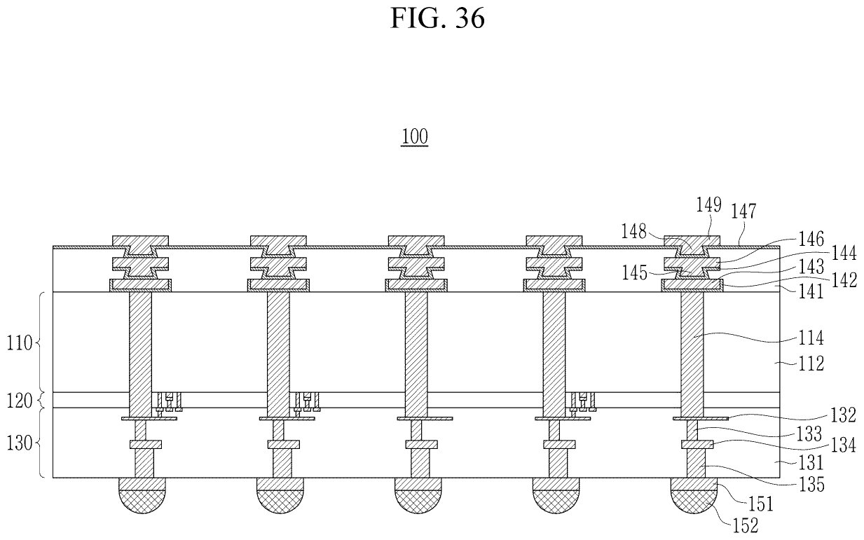

FIG. 36 is a cross-sectional view illustrating a step of removing the sixth photoresist patterns PRP6.

Referring to FIG. 36, the sixth photoresist patterns PRP6 are removed. In an embodiment, the sixth photoresist patterns PRP6 may be removed by at least one of etching, ashing, and stripping.

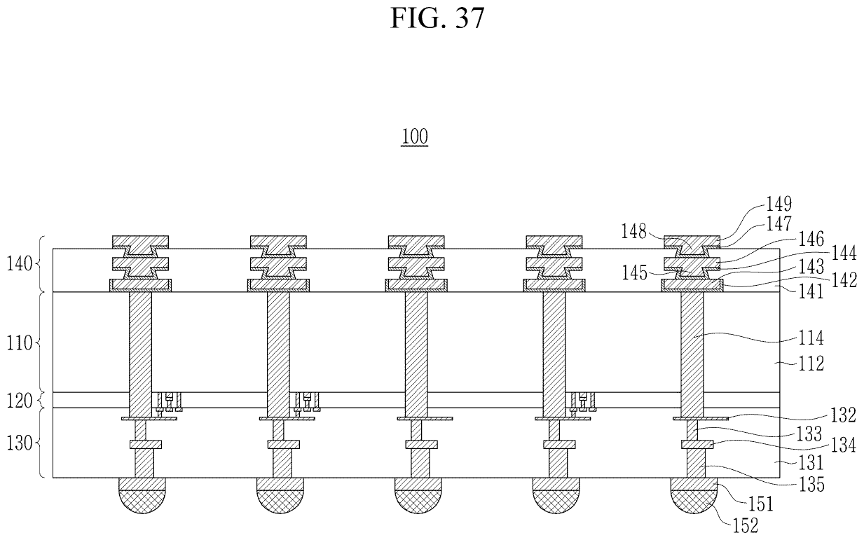

FIG. 37 is a cross-sectional view illustrating a step of removing the exposed portions of the third seed metal layer 147.

Referring to FIG. 37, the exposed portions of the third seed metal layer 147 are etched.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the present invention as set forth in the appended claims.

What is claimed is:

1. A semiconductor structure comprising:
a first redistribution line;
a first redistribution via on the first redistribution line, the first redistribution via having a width in a horizontal direction that decreases from a bottom end of the first redistribution via to a top end of the first redistribution via;
a second redistribution line on the first redistribution via;
a dielectric surrounding the first redistribution line, the first redistribution via, and the second redistribution line; and
a first seed metal layer between a lower surface of the first redistribution via and the first redistribution line, between a side surface of the first redistribution via and the dielectric, and between a lower surface of the second redistribution line and the dielectric.

2. The semiconductor structure of claim 1, further comprising:
a second redistribution via on the second redistribution line and in the dielectric,
wherein the second redistribution via has a width in the horizontal direction that decreases from a bottom end of the second redistribution via to a top end of the second redistribution via.

3. The semiconductor structure of claim 2, further comprising:
a bonding pad on the second redistribution via.

4. The semiconductor structure of claim 3, further comprising:
a second seed metal layer between a lower surface of the second redistribution via and the second redistribution line, between a side surface of the second redistribution via and the dielectric, and between a lower surface of the bonding pad and the dielectric.

5. The semiconductor structure of claim 1, wherein the first redistribution via and the second redistribution line have an integrated shape.

6. The semiconductor structure of claim 1, wherein the dielectric is a photoimageable dielectric (PID).

7. The semiconductor structure of claim 1, wherein the first seed metal layer continuously extends between the lower surface of the first redistribution via and the first redistribution line, between the side surface of the first redistribution via and the dielectric, and between the lower surface of the second redistribution line and the dielectric.

8. The semiconductor structure of claim 1, wherein a cross-sectional shape of the first redistribution via in the horizontal direction includes a trapezoid shape, a circular shape, an oval shape, a rectangular shape, or a hexagonal shape.

9. The semiconductor structure of claim 1, wherein an area of the lower surface of the first redistribution via is larger than an area of an upper surface of the first redistribution via.

10. The semiconductor structure of claim 1, wherein an angle between an upper surface of the first redistribution line and a side surface of the first seed metal layer is in a range from about 100° to about 110°.

11. The semiconductor structure of claim 1, wherein the width of the lower surface of the first redistribution via and lower side portions of the first seed metal layer between the first redistribution via and the dielectric, in the horizontal direction is in a range from about 8 um to about 10 μm.

12. The semiconductor structure of claim 1, wherein a height from the lowermost surface of the first seed metal layer to an upper surface of the first redistribution via in a vertical direction is in a range from about 3 μm to about 3.5 μm.

13. A semiconductor chip comprising:
a substrate including a front side and a back side opposite to the front side;
an active layer on the front side the active layer including an integrated circuit structure;
a wiring layer on the active layer; and
a back side redistribution structure on the back side of the substrate,
wherein the back side redistribution structure includes:
a plurality of first redistribution lines;
a plurality of redistribution vias on the plurality of first redistribution lines, each of plurality of redistribution vias having a width in a horizontal direction that decreases from a bottom end of each of the plurality of redistribution vias to a top end of each of the plurality of redistribution vias;
a plurality of second redistribution lines on the plurality of redistribution vias;
a dielectric surrounding the plurality of first redistribution lines, the plurality of redistribution vias, and the plurality of second redistribution lines;
a plurality of seed metal layers disposed between lower surfaces of the plurality of redistribution vias and the plurality of first redistribution lines, between side surfaces of the plurality of redistribution vias and the dielectric; and between the dielectric and lower surfaces of the plurality of second redistribution lines.

14. The semiconductor chip of claim 13, further comprising:
a plurality of through silicon vias that extends from the front side to the back side of the substrate.

15. The semiconductor chip of claim 14, wherein the plurality of through silicon vias are electrically connected to the back side redistribution structure.

16. A method for manufacturing a semiconductor structure, the method comprising:
forming a first redistribution line and a dielectric surrounding a side surface of the first redistribution line, on a back side of a substrate;
forming a first photoresist on the dielectric and the first redistribution line;
patterning the first photoresist to form a first photoresist pattern on the first redistribution line, wherein the first photoresist pattern has a width in a horizontal direction that decreases from a bottom end of the first photoresist pattern to a top end of the first photoresist pattern;
depositing an additional dielectric on the dielectric, the first redistribution line, and the first photoresist pattern;
removing the first photoresist pattern to expose an upper surface of the first redistribution line;
depositing a seed metal layer on the exposed first redistribution line and the additional dielectric;
forming a second photoresist on the seed metal layer;
patterning on the second photoresist to form a second photoresist pattern on the seed metal layer, the second photoresist pattern formed to expose a portion of the seed metal layer; and
depositing a conductive material on the exposed a portion of the seed metal layer to form a redistribution via on the first redistribution line and to form a second redistribution line on the redistribution via.

17. The method of claim 16, wherein the depositing of the seed metal layer is performed by electroless plating.

18. The method of claim 16, wherein the depositing of the conductive material is performed by electroplating.

19. The method of claim 16, wherein the forming of the redistribution via on the first redistribution line and the forming of the second redistribution line on the redistribution via is performed by a single process.

20. The method of claim 16, further comprising:
planarizing the additional dielectric to expose the first photoresist pattern after the depositing of the additional dielectric on the dielectric, the first redistribution line, and the first photoresist pattern.
